(19) United States
(12) Patent Application Publication
(10) Pub. No.: US 2012/0141674 A1
(43) Pub. Date: Jun. 7, 2012

(54) EVAPORATOR AND METHOD FOR DEPOSITING ORGANIC MATERIAL

(76) Inventors: Il-Soo PARK, Yongin-City (KR); Jun-Sik Oh, Yongin-city (KR); Won-Hyouk Jang, Yongin-city (KR)

(21) Appl. No.: 13/197,876

(22) Filed: Aug. 4, 2011

(30) Foreign Application Priority Data
Dec. 3, 2010 (KR) 10-2010-0122703

(51) Int. Cl. C23C 16/448; C23C 16/455

(52) U.S. Cl. 427/248.1; 118/726

(57) ABSTRACT

An evaporator for depositing material on a substrate includes a crucible configured to receive a deposition material, and a plurality of nozzles in fluid communication with the crucible and facing the substrate, the nozzles projecting away from the crucible and being arranged in a first direction along the crucible, at least two of the nozzles being inclined with respect to a normal to the substrate.

### BACKGROUND

1. Field

The described technology relates generally to an evaporator and a material depositing method. More particularly, the described technology relates generally to an evaporator on which a plurality of nozzles are linearly disposed and an organic material depositing method using the same.

2. Description of the Related Art

An organic light emitting diode (OLED) display represents a display device that has self light emitting characteristics and needs no additional light source. The OLED display is widely used, as it exhibits advantages in terms of reduced size, reduced thickness, low power consumption, and high luminance.

In general, the OLED display includes an organic light emitting element having an anode, an organic emission layer, and a cathode. The organic light emitting element receives holes and electrons from the anode and the cathode to form excitons, and the excitons are transformed to a ground state to emit light. The organic emission layer of the organic light emitting element may be formed by using an evaporator for evaporating an organic material and spraying it on a substrate.

The above information disclosed in this Background section is only for enhancement of understanding of the background of the described technology and therefore it may contain information that does not form the prior art that is already known in this country to a person of ordinary skill in the art.

### SUMMARY

An exemplary embodiment may provide an evaporator for depositing material on a substrate, the evaporator including a crucible configured to receive a deposition material, and a plurality of nozzles in fluid communication with the crucible and facing the substrate, the nozzles projecting away from the crucible and being arranged in a first direction along the crucible, at least two of the nozzles being inclined with respect to a normal to the substrate.

The inclined nozzles may be positioned at an oblique angle with respect to the first direction.

At least two of the inclined nozzles may have different inclined angles with respect to each other.

The plurality of nozzles may be symmetric with respect to an axis parallel to the normal to the substrate.

The at least two inclined nozzles may have an inclination angle of about 30° or less.

The nozzles may be disposed at regular intervals.

The at least two inclined nozzles may be external to the crucible.

Sidewalls of the at least two inclined nozzles may be external to an upper surface of the crucible and define an oblique angle with the first direction.

Internal widths of the nozzles may be substantially constant.

Another embodiment may provide a method for depositing a deposition material on a substrate with an evaporator, the method including filling a crucible of the evaporator with the deposition material, the evaporator including a plurality of nozzles in fluid communication with the crucible and projecting away from the crucible, positioning the evaporator, such that the nozzles are arranged in a first direction along the crucible and face the substrate, and moving the evaporator in a second direction substantially perpendicular to the first direction to deposit evaporated deposition material from the crucible on the substrate through the nozzles, at least two of the nozzles depositing the deposition material at an inclined direction with respect to a normal to the substrate.

Depositing the organic material at an inclined direction may include spraying the deposition material at an oblique angle with respect to the first direction.

Depositing the deposition material at an inclined direction may include spraying the deposition material in at least two different inclined directions with respect to the normal to the substrate.

Depositing the deposition material may include arranging the nozzles in a symmetric structure with respect to an axis parallel to the normal to the substrate.

Depositing the deposition material at an inclined direction may include spraying the deposition material at an angle of about 30° or less with respect to the normal to the substrate.

Depositing the deposition material may include arranging the nozzles at regular intervals along the first direction on the evaporator.

Depositing the deposition material at an inclined direction may include optimizing the inclined direction by using a genetic algorithm.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic diagram of an organic material deposition device according to an exemplary embodiment.

FIG. 2 illustrates a perspective view of an evaporator according to an exemplary embodiment.

FIG. 3 illustrates a cross-sectional view of a crucible and a nozzle of an evaporator according to an exemplary embodiment.

FIG. 4 illustrates a relationship between a nozzle direction of an evaporator according to an exemplary embodiment and a deposition coordinate.

FIG. 5 illustrates a graph indicating uniformity of an organic layer on a substrate using an evaporator according to a comparative example.

FIG. 6 and FIG. 7 illustrate graphs indicating uniformity of an organic layer on a substrate using an evaporator according to an exemplary embodiment.

### DETAILED DESCRIPTION

Korean Patent Application No. 10-2010-0122703, filed on Dec. 3, 2010, in the Korean Intellectual Property Office, and entitled: “Evaporator and Method for Depositing Organic Material,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer (or element) is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

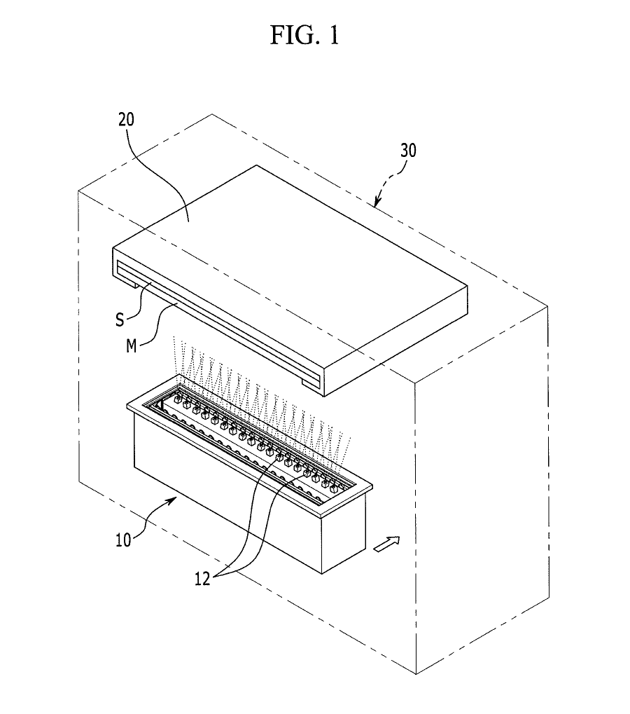

FIG. 1 illustrates a schematic diagram of an organic material deposition device according to an exemplary embodiment. Referring to FIG. 1, the organic material deposition device may include an evaporator 10, a fixing member 20, and a process chamber 30.

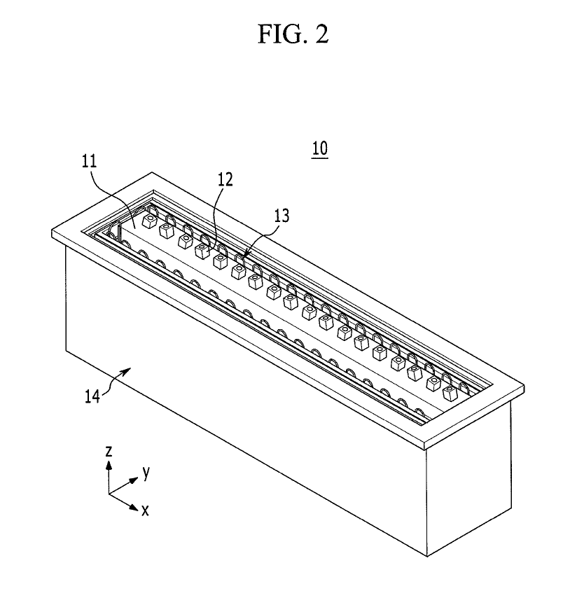

The evaporator 10 deposits an organic material on a substrate (S), and includes a crucible 11 (FIG. 2) for storing the organic material and evaporating it. The evaporator 10 further includes a nozzle 12 for spraying the organic material. The evaporator 10 may be formed to be a linear evaporator, in which a plurality of nozzles 12 may be arranged in series along a first direction on the evaporator 10, as will be described in more detail below.

The substrate (S) may be positioned to face the nozzle 12 of the evaporator 10 with a mask (M), and may be fixed to the fixing member 20. The mask (M) may define an organic layer pattern on the substrate (S), e.g., openings may be formed between shields for blocking deposition of the organic material, so the organic material may be deposited on the substrate (S) through the openings of the mask (M).

For example, as illustrated in FIG. 1, the substrate (S) and the mask (M) may be fixed to the fixing member 20, and may be positioned to face the nozzles 12 of the evaporator 10, e.g., the mask (M) may be positioned between the evaporator 10 and the substrate (S). However, any configuration of the substrate (S) and the mask (M) relative to the fixing member 20 is within the scope of the example embodiments. For example, the substrate (S) and the mask (M) may be fixed to separate fixing members. Further, the fixing member for fixing the substrate (S) may be formed in various manners, e.g., a tray with a gripper or an electrostatic chuck.

The process chamber 30 may provide a space for receiving the evaporator 10 and the fixing member 20 and for performing a deposition process. During the deposition process, the inside of the process chamber 30 may be maintained at a vacuum state, e.g., the process chamber 30 may be connected to a vacuum pump (not shown).

In order to form a plurality of organic layers on a single substrate, the deposition process may be performed in a plurality of process chambers 30, e.g., the process chambers may be classified as an inline type or a cluster type in accordance with the substrate (S) transfer among the plurality of the process chambers 30. For example, when the process chambers 30 are disposed according to the inline type, the substrate (S) may be sequentially transferred between the process chambers 30 while being fixed to the fixing member 20, i.e., the substrate (S) and the fixing member 20 may be fixed to each other and move together between the process chambers 30, e.g., via a movement mechanism of the fixing member 20. In another example, when the process chambers 30 are disposed according to the cluster type, the substrate (S) may be transferred between the process chambers 30 without the fixing member 20, i.e., a fixing member 20 may be attached to each process chamber to receive a movable substrate (S), e.g., via a robot arm. The mask (M) may be transferred to each process chamber 30 together with or separately from the substrate (S), or may be fixedly installed in the process chamber 30.

In the present exemplary embodiment, the substrate (S) and the mask (M) may be arranged in the process chamber 30. As illustrated in FIG. 1, when the substrate (S) and the mask (M) stop in the process chamber 30, the evaporator 10 may move to deposit the organic material on the substrate (S). For this purpose, an evaporator guide member (not shown) may be installed at a bottom part of the evaporator 10, so the evaporator 10 may move in a second direction (indicated by an arrow in FIG. 1), i.e., a direction substantially perpendicular to the first direction in which the plurality of nozzles 12 is arranged during the deposition process. For example, as illustrated in FIG. 1, the substrate (S) may be disposed in a horizontal plane to deposit the organic material, but the substrate (S) may be also vertically disposed to deposit the same in order to suppress non-movement of the substrate (S) because of weight.

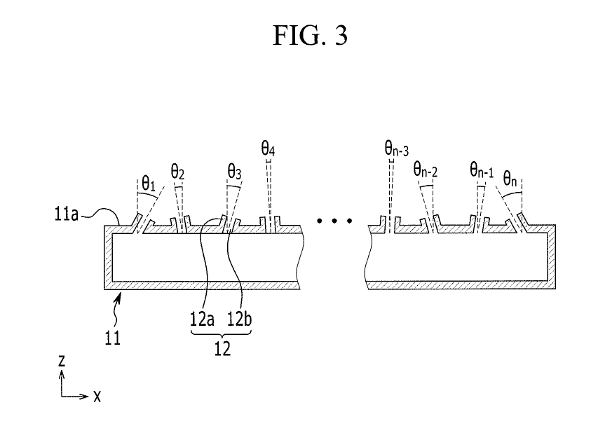

FIG. 2 illustrates a perspective view of the evaporator 10 according to an exemplary embodiment, and FIG. 3 illustrates a cross-sectional view of the crucible 11 and the nozzle 12 according to an exemplary embodiment. A configuration of the evaporator 10 according to an exemplary embodiment will now be described in detail.

Referring to FIG. 2, the evaporator 10 may include the crucible 11 for receiving the organic material and the nozzle 12 in, e.g., fluid, communication with the crucible 11. The evaporator 10 may further include a heater 13 outside the crucible 11 so as to apply heat to the organic material in the crucible 11. The evaporator 10 may further include a housing 14 for receiving the crucible 11 and the heater 13.

In order to efficiently transmit the heat generated by the heater 13 to the organic material received by the crucible 11 and to minimize a temperature deviation inside the crucible 11, the crucible 11 may be made of a metal with an excellent thermal conductivity, e.g., copper or aluminum. The heater 13 may be disposed on both sides of the crucible 11 with respect to the y-axis in the present exemplary embodiment, e.g., the heater 13 may be disposed on one of the sides of the crucible 11 or it may wrap the whole crucible 11 except the side having the nozzle 12. That is, the heater 13 may be disposed in any suitable form or pattern that provides sufficient heat to control the organic material in the crucible 11, e.g., to ensure that the organic material reaches a vaporizing temperature or a sublimation temperature.

The housing 14 may receive the crucible 11 and the heater 13, and may fix them. The housing 14 may be formed to include a thermal insulation material to reflect the heat output by the heater 13 toward the crucible 11, and to simultaneously prevent the heat from being output outside the evaporator 10. In addition, a thermal insulating plate (not shown) may be disposed between the housing 14 and the heater 13.

The housing 14 may further include a coolant. For example, the housing 14 may be formed as a double-wall structure including an interior wall and an exterior wall with a space therebetween for a coolant, i.e., the coolant may flow between the interior wall and the exterior wall. In another example, a cooling device, additionally or alternatively, may be formed outside the housing 14. Accordingly, when the coolant is formed, the heat output by the heater 13 and the crucible 11 may be prevented from being output outside the evaporator 10.

Referring to FIG. 3, according to example embodiments, at least two of the nozzles 12 in the evaporator 10 may be angled with respect to a normal to the evaporator 10, i.e., with respect to the z-axis. Therefore, when the organic material is deposited on the substrate (S) by using the linear evaporator 10, i.e., an evaporator on which a plurality of nozzles 12 is disposed along a single direction, the amount of the organic material deposited on the substrate (S) may be substantially uniform. In contrast, when the conventional nozzles are not angled, a relatively large amount of the organic material may be deposited in a center of a substrate, i.e., a center relative to the x-axis, and a relatively lower amount of the organic material may be deposited at edges of the substrate, thereby reducing uniformity of the organic layer.

In detail, referring to FIG. 2 and FIG. 3, in order to improve the uniformity of an organic layer, i.e., thickness long the z-axis, formed by using the evaporator 10, the nozzles 12 may be disposed at regular intervals with at least two nozzles 12, among a plurality of nozzles 12 that are in fluid communication with the crucible 11, that are inclined with respect to the vertical direction (z-axis direction) toward the substrate (S) from the evaporator 10. In further detail, each nozzle 12 of the plurality of nozzles 12 includes sidewalls 12a that protrude, i.e., project, from an upper surface 11a of the crucible 11 toward the substrate (S) to define a channel 12b for spraying the organic material toward the substrate (S). The sidewalls 12a of at least two nozzles 12 may be inclined at an oblique angle θ with respect to a normal to the upper surface 11a of the crucible 11, so that channels 12b of the inclined nozzles 12 may be inclined as well to direct the sprayed organic material at an oblique angle θ toward the substrate (S). For example, internal widths of the nozzles 12, i.e., widths of the channels 12b of the plurality of nozzles 12, may be constant, i.e., a same distance along the x-axis between sidewalls 12a of each nozzle 12, so only a deposition angle of the organic material may change due to the inclined angle of the nozzles.

According to exemplary embodiments, at least two of the nozzles 12 slanted with respect to the vertical direction (z-axis direction) facing the substrate (S) may be formed to have different inclined angles. For example, each of the nozzles 12 may have a different oblique angle θ, e.g., each of θ₁ through θ₄ may be positioned at a different angle with respect to a normal to the upper surface 11a of the crucible 11. The angle for the nozzle 12 to be inclined with respect to the vertical direction facing the substrate (S) by the evaporator 10 is called an inclined angle of the nozzle.

Accordingly, since at least two of the nozzles 12 have inclined structures, an amount of the organic material gathered in the center of the substrate (S) may be reduced, and an amount of the organic material at edges of the substrate (S) may increase to improve deposition uniformity of the organic layer. The uniformity of the organic layer deposited on both sides of the substrate (S) in the direction in which the nozzles 12 are arranged may be improved by forming at least two of the inclined nozzles 12 to have different inclined angles. Also, by disposing the nozzles 12 at regular intervals along the first direction, e.g., along the x-axis, the pressure inside the crucible 11 may be maintained at a substantially constant value, thereby using the organic material uniformly through each nozzle 12 and suppressing deformation of the organic material, e.g., caused by an increase of pressure. It is noted that one interval between nozzles 12 refers to a distance along the first direction between centers of two adjacent nozzles 12, so nozzles 12 at regular intervals may have constant distances therebetween along the first direction.

For example, referring to FIG. 3, a plurality of the nozzles 12 may be slanted in the first direction (x-axis direction) in which the nozzles 12 are arranged with respect to the vertical direction (z-axis direction) toward the substrate (S) from the evaporator 10. That is, at least two nozzles 12 may be inclined in the first direction, e.g., the inclined nozzles 12 may define an oblique angle with the x-axis and not with the y-axis. It is noted that since the evaporator 10 moves in the y-axis direction, a non-uniformity of organic material deposition problem along the y-axis direction may be minimized or substantially eliminated, e.g., as compared to the deposition non-uniformity caused by disposal of the nozzles in the x-axis direction. However, example embodiments are not restricted thereto, and the nozzles 12 may be inclined in the arrangement direction (x-axis direction) of the nozzles 12 and in the moving direction (y-axis direction) of the evaporator 10.

In addition, even though FIG. 3 shows different inclined angles θ00 of adjacent, i.e., neighboring, nozzles 12, e.g., angles θ₁ through θ₄ are different from each other, example embodiments are not restricted thereto. For example, θ₁ and θₙ may be slanted at a substantially same angle, while the remaining angles of the nozzles 12 may be substantially the same.

For example, referring to FIG. 3, the inclined angles (θ₁, θ₂, . . . θₙ) of the nozzle 12 on both sides may be formed to be symmetric with each other along the x-axis direction, e.g., θ₁=θₙ, θ₂=θₙ₋₁, θ₃=θₙ₋₂, . . . That is, both side of the nozzles 12 may be formed to be symmetric with respect to a symmetry axis passing along the z-axis (FIG. 2). Therefore, the amount of the organic material deposited on both sides of the substrate (S) along the direction (x-axis direction) in which the nozzles 12 are arranged may be controlled to be uniform. However, example embodiments are not restricted thereto, and when the inclined angles of the nozzles 12 are not formed to be symmetric, the nozzles 12 may be arranged, e.g., in terms of numbers and inclination and geometry, for uniformly forming the organic layer over the substrate (S).

In addition, when the inclined angle θ of the nozzle 12 is large, the amount of the organic material not deposited on the substrate (S) but sprayed outside the substrate (S) and wasted may be increased. Therefore, the inclined angle 0 of each nozzle 12 may be optimized, e.g., each angle θ may be controlled to be less than about 30°.

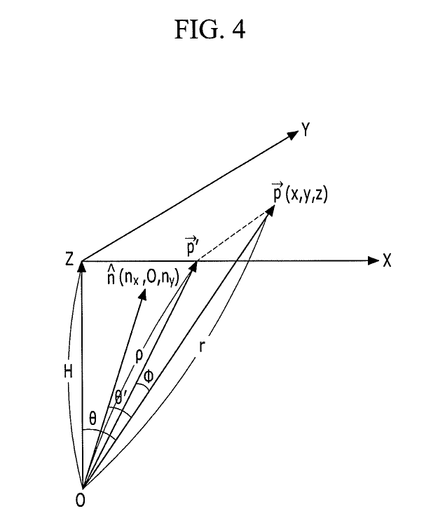

FIG. 4 shows a relationship between the nozzle 12 direction of the evaporator 10 according to an exemplary embodiment and a deposition coordinate. Referring to FIG. 4, a relationship between the inclined angle θ of the nozzle 12 in the evaporator 10 and the amount of the deposited organic material on the substrate (S), as well as a method for optimizing the inclined angle of the nozzle 12, will be described.

FIG. 4 shows the position of the nozzle as the origin (O) and a deposition point P at which the organic material is deposited on the substrate (S). The deposition point P is shown as a position vector \vec{p}(x,y,z). A distance from the nozzle to the deposition point, i.e., a distance between points O and P, and the vertical distance from the nozzle to the substrate, i.e., a distance between point O and point Z on the x-axis, are indicated as r and H, respectively. The angle between the vertical vector from the nozzle to the substrate and the position vector \vec{p} of the deposited point, i.e., the angle between r and H, is shown as θ and satisfies Equation 1.

$$cos θ = \frac{H}{r} \qquad Equation 1$$

As described above, the nozzles can be formed to be inclined in the direction in which the nozzles are arranged, and FIG. 4 shows the nozzle-inclined direction as the unit vector \hat{n}(nₓ, 0, n_{z}). Also, the angle between the unit vector \hat{n} indicating the nozzle inclined direction and the position vector \vec{p} at the deposition point is shown as θ′. The angle θ′ may be expressed by Equation 2, i.e., by using an inner product of the two vectors.

$$cos {θ}^{′} = \frac{{n}^{⋒} \cdot \vec{p}}{\vert \vec{p} \vert} = \frac{{n}_{x} x + {n}_{z} z}{r} \qquad Equation 2$$

Further, the vector generated by transferring the position vector \vec{p} at the deposition point to the XZ plane is shown as \vec{p}′. The size ρ of \vec{p}′ is expressed in Equation 3.

ρ²=x²+z² Equation 3

Further, as shown in FIG. 4, when the angle between \vec{p} and \vec{p′} is set to be Φ, the relationship between ρ and r is expressed in Equation 4.

ρ=r cos φ Equation 4

The flux of the organic material sprayed by the nozzle is expressed as a cos ⁿθ′ type Gaussian function. Together with this, when the position of the deposition point P and the distance r from the nozzle to the deposition point P are considered, the amount of the organic material deposited to the deposition point while the nozzle is stopped can be expressed as

$${cos }^{n} {θ}^{′} = \frac{cos θ}{{r}^{2}} .$$

Therefore, when the evaporator 10 on which the nozzles 12 are disposed moves in the direction vertical to the nozzles-arranged direction, i.e., along the y-axis of FIG. 2, and deposits the organic material on the substrate (S), the amount of the organic material deposited at a specific deposition point P by the nozzle 12 may be found by integrating the amount of the organic material while the nozzle is stopped with respect to the y-axis. The amount of the organic material deposited to the deposition point P by one nozzle 12 having an inclined angle is expressed by Equation 5 below.

$$\begin{matrix}f ( θ ) = {\int }_{- ∞}^{+ ∞} {cos}^{n} {θ}^{′} \frac{cos θ}{{r}^{2}} d y \\ = {\int }_{- ∞}^{+ ∞} {( \frac{{n}_{x} x + {n}_{z} z}{r} )}^{n} \frac{H / r}{{r}^{2}} d y \\ = {\int }_{- ∞}^{+ ∞} \frac{{( {n}_{x} x + {n}_{z} z )}^{n} H}{{r}^{n + 3}} d y\end{matrix} \qquad Equation 5$$

The amount of the organic material deposited to the deposition point P can be expressed by substituting y=p tan φ and dy=ρsec²φdφ in Equation 5. Further, Equation 4 may be applied to a resultant expression to provide Equation 6 below.

$$\begin{matrix}f ( θ ) = {\int }_{- π / 2}^{+ π / 2} \frac{{( {n}_{x} x + {n}_{z} z )}^{n} H ρ {sec}^{2} φ}{{( ρ sec φ )}^{n + 3}} d φ \\ = \frac{{( {n}_{x} x + {n}_{z} z )}^{n} H}{{ρ}^{n + 2}} {\int }_{- π / 2}^{+ π / 2} {cos}^{n + 1} φ d φ\end{matrix} \qquad Equation 6$$

Accordingly, when the inclined angle of the nozzle 12 is given, the amount of the organic material deposited to a specific deposition point P (x, y, z) by the nozzle 12 can be calculated by using the unit vector \hat{n}(nₓ, O, n_{z}), i.e., the inclined direction of the nozzle 12.

Through this calculation, the amount of the organic material deposited to each point of the substrate (S) by each nozzle 12 may be calculated when inclined angles of a plurality of nozzles 12 are given in a random manner. Further, the uniformity of the organic layer formed on the substrate (S) may be checked by adding the amounts of the deposited organic material in order to calculate the amount of the organic material deposited on the entire substrate (S). Since the uniformity of the organic layer deposited by the nozzles 12 may be calculated when the nozzles 12 have random inclined angles, an optimized inclined angle of the nozzles 12 may be acquired.

For example, a genetic algorithm may be used to find the optimized inclined angle of the nozzle 12. The genetic algorithm finds the appropriate solution for a given problem by gradually changing the solution based on predetermined data.

In order to optimize the inclined angle of the nozzle by using the genetic algorithm, the uniformity of the organic layer is calculated by applying a random nozzle inclined angle, so the nozzle inclined angle may be corrected in accordance with the calculation result so as to improve the uniformity of the organic layer. This process may be performed repeatedly to acquire a nozzle inclined angle having desirable organic layer uniformity.

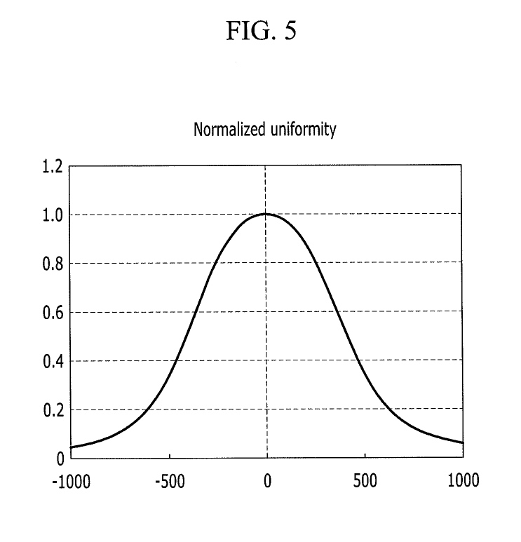

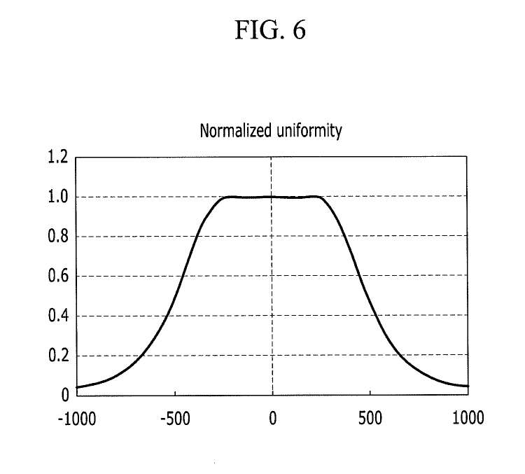

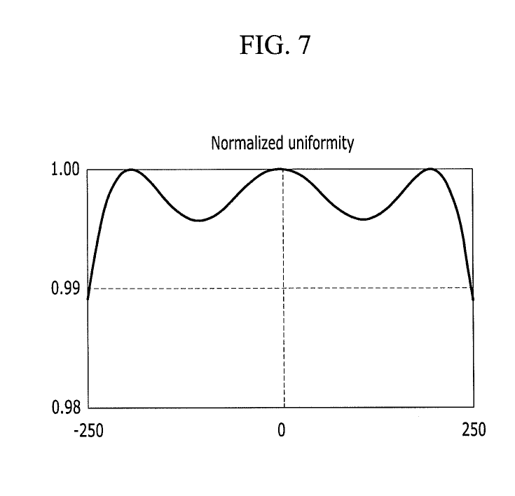

An effect of depositing the organic material by the evaporator 10 according to an exemplary embodiment will now be described with reference to FIGS. 5-7. FIG. 5 illustrates a graph indicating uniformity of an organic layer on a substrate using an evaporator according to a comparative example, and FIG. 6 and FIG. 7 illustrate graphs indicating uniformity of an organic layer on a substrate using an evaporator according to an exemplary embodiment. In the comparative example and the exemplary embodiment, a linear evaporator with twenty-four (24) uniformly disposed nozzles is used. Also, the flux of the organic material sprayed by one nozzle is set to be cos ^{3.4}θ, and the vertical distance between the evaporator and the substrate is set to be 340 mm. Further, the deposited angle of the nozzle generated by using the genetic algorithm is applied to the exemplary embodiment.

TABLE 1

| Nozzle position | 1 | 2 | 3 | 4 | 5 | 6 | 7 | 8 | 9 | 10 | 11 | 12 |
|---|---|---|---|---|---|---|---|---|---|---|---|---|
| Nozzle inclined | 12.4 | 11.9 | 17.6 | 13.8 | 18.9 | 20.0 | 19.5 | 9.2 | 8.3 | −17.3 | −19.8 | 15.9 |
| angle(θ) | | | | | | | | | | | | |

The nozzle positions 1 and 12 indicate the outermost edge and the center of the evaporator 10 respectively. The 12 nozzles were formed to be symmetrical with the nozzle inclined angles of Table 1. Also, when the nozzle inclined angle is a positive number, it means that the nozzle is inclined in the direction toward the edge of the evaporator from the center. When the nozzle inclined angle is a negative number, it means that the nozzle is inclined in the direction toward the center of the evaporator from the edge thereof.

Referring to FIG. 5, when the evaporator according to the comparative example is used, the thickness of the organic layer shows the Gaussian distribution. Therefore, the uniformity was poor.

However, referring to FIG. 6, when evaporator 10 according to the exemplary embodiment is used, the thickness of the organic layer is substantially constant within a predetermined range. FIG. 7 shows a magnified center of FIG. 6, showing that the uniformity of the organic layer is far greater than 99% within a predetermined range.

Accordingly, the evaporator 10 with the inclined nozzles 12 may improve deposition uniformity of the organic layer. Further, since the gaps between the nozzles 12 have regular intervals, the pressure within the crucible 11 may be maintained, i.e., an internal pressure within the crucible may be maintained at a constant value, so the amount of the organic material sprayed by the nozzles 12 may be disposed uniformly. Further, since no internal barrier rib is used, the problem of deformation of the organic material caused by an increase of the internal pressure of the crucible may be suppressed. Also, process efficiency may be improved by increasing the maintenance period of the evaporator.

In contrast, a conventional evaporator, e.g., a conventional linear evaporator, may form a relatively thick organic layer in a center of a substrate, while forming a relatively thin organic layer at an edge of the substrate, thereby deteriorating uniformity of the organic layer. Further, while attempts were made to improve deposition uniformity of the conventional evaporator by forming gaps between nozzles with different widths, i.e., relatively bigger gaps in a center of the evaporator and relatively smaller gaps at edges of the evaporator, when the gaps of the nozzles are differently formed, the pressure inside the crucible connected to the nozzle may be non-uniform, thereby depositing non-uniform amounts through the different nozzles to form a layer with a non-uniform thickness.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An evaporator for depositing material on a substrate, the evaporator comprising:
a crucible configured to receive a deposition material; and
a plurality of nozzles in fluid communication with the crucible and facing the substrate, the nozzles projecting away from the crucible and being arranged in a first direction along the crucible, at least two of the nozzles being inclined with respect to a normal to the substrate.

2. The evaporator as claimed in claim 1, wherein the inclined nozzles are positioned at an oblique angle with respect to the first direction.

3. The evaporator as claimed in claim 1, wherein at least two of the inclined nozzles have different inclined angles with respect to each other.

4. The evaporator as claimed in claim 1, wherein the plurality of nozzles is symmetric with respect to an axis parallel to the normal to the substrate.

5. The evaporator as claimed in claim 1, wherein the at least two inclined nozzles have an inclination angle of about 30° or less.

6. The evaporator as claimed in claim 1, wherein the nozzles are disposed at regular intervals.

7. The evaporator as claimed in claim 1, wherein the at least two inclined nozzles are external to the crucible.

8. The evaporator as claimed in claim 7, wherein sidewalls of the at least two inclined nozzles are external to an upper surface of the crucible and define an oblique angle with the first direction.

9. The evaporator as claimed in claim 1, wherein internal widths of the nozzles are substantially constant.

10. A method for depositing a deposition material on a substrate with an evaporator, the method comprising:
filling a crucible of the evaporator with the deposition material, the evaporator including a plurality of nozzles in fluid communication with the crucible and projecting away from the crucible;
positioning the evaporator, such that the nozzles are arranged in a first direction along the crucible and face the substrate; and
moving the evaporator in a second direction substantially perpendicular to the first direction to deposit evaporated deposition material from the crucible on the substrate through the nozzles, at least two of the nozzles depositing the deposition material at an inclined direction with respect to a normal to the substrate.

11. The method as claimed in claim 10, wherein depositing the organic material at an inclined direction includes spraying the deposition material at an oblique angle with respect to the first direction.

12. The method as claimed in claim 10, wherein depositing the deposition material at an inclined direction includes spraying the deposition material in at least two different inclined directions with respect to the normal to the substrate.

13. The method as claimed in claim 10, wherein depositing the deposition material includes arranging the nozzles in a symmetric structure with respect to an axis parallel to the normal to the substrate.

14. The method as claimed in claim 10, wherein depositing the deposition material at an inclined direction includes spraying the deposition material at an angle of about 30° or less with respect to the normal to the substrate.

15. The method as claimed in claim 10, wherein depositing the deposition material includes arranging the nozzles at regular intervals along the first direction on the evaporator.

16. The method as claimed in claim 10, wherein depositing the deposition material at an inclined direction includes optimizing the inclined direction by using a genetic algorithm.
